(19) United States
(12) Patent Application Publication
(10) Pub. No.: US 2023/0420599 A1
(43) Pub. Date: Dec. 28, 2023

(54) HIGH FLUX LED WITH LOW OPERATING VOLTAGE UTILIZING TWO P-N JUNCTIONS CONNECTED IN PARALLEL AND HAVING ONE TUNNEL JUNCTION

(71) Applicant: Lumileds LLC, San Jose, CA (US)

(72) Inventor: Robert Armitage, Cupertino, CA (US)

(73) Assignee: Lumileds LLC, San Jose, CA (US)

(21) Appl. No.: 18/211,923

(22) Filed: Jun. 20, 2023

Related U.S. Application Data
(60) Provisional application No. 63/355,356, filed on Jun. 24, 2022.

(51) Int. Cl. H01L 33/00; H01L 33/06; H01L 21/60; H01L 33/32; H01L 33/08

(52) U.S. Cl. CPC H01L 33/0016; H01L 33/06; H01L 33/007; H01L 21/60; H01L 33/32; H01L 33/08; H01L 2021/60052

(57) ABSTRACT

Provided is an LED comprised of a first and a second p-n junction deposited sequentially on the same wafer. The first and second junctions have opposite orders of deposition of the n- and p-layers. One light-emitting active region is embedded between the n- and p-layers of the first junction and another light-emitting active region is embedded between the n- and p-layers of the second junction. Contacts are processed such that forward current can be passed in parallel through both of the junctions using a single voltage source. For a given forward current, the LED operates at lower voltage with higher optical flux and efficiency.

### CROSS-REFERENCE TO RELATED APPLICATIONS

This application claims priority to U.S. Provisional Application No. 63/355,356, filed Jun. 24, 2022, the entire disclosure of which is hereby incorporated by reference herein.

### GOVERNMENT LICENSE RIGHTS

This invention was made with U.S. Government support under Award No. DE-EE009163 awarded by Department of Energy (DOE). The U.S. Government has certain rights in the invention.

### TECHNICAL FIELD

Embodiments of the disclosure generally relate to arrays of light emitting diode (LED) devices and methods of manufacturing the same. More particularly, embodiments are directed to light emitting diode devices having a first and a second p-n junction deposited sequentially on the same wafer, the first and second junctions having opposite orders of deposition of the n- and p-layers. One light-emitting active region is embedded between the n- and p-layers of the first junction, and another light-emitting active region is embedded between the n- and p-layers of the second junction.

### BACKGROUND

A light emitting diode (LED) is a semiconductor light source that emits visible light when current flows through it. LEDs combine a P-type semiconductor with an N-type semiconductor. LEDs commonly use a III-group compound semiconductor. A III-group compound semiconductor provides stable operation at a higher temperature than devices that use other semiconductors. The III-group compound is typically formed on a substrate formed of sapphire or silicon carbide (SiC).

Indium gallium nitride (InGaN)-based LEDs in general, and green LEDs in particular, suffer from a problem known as “efficiency droop.” Droop refers to a non-thermal decrease in external quantum efficiency (EQE) of the LED as the current density increases. Droop is caused by the increase in the non-radiative Auger recombination rate as the carrier density increases. The optimization of the multi-quantum well design to minimize Auger recombination (droop) has been the subject of extensive research over the years. For green LEDs in particular, it has been found that design changes needed to improve droop unfortunately also increase the forward voltage. The interaction between droop and forward voltage makes it very difficult to further improve the lumen/watt and power conversion efficiencies (PCE) of green LEDs operated at high current densities.

Reducing the current density is a known straightforward way to reduce the forward voltage and increase the EQE and PCE. Increasing the total emitter area would be a way to decrease the current density while maintaining fixed light output, but that approach increases system cost and is not possible for applications requiring small optical source sizes. The tunnel junction cascade LED is a device design that has been proposed to obtain high flux from a small source size at lower current density. In a cascade LED two or more p-n junctions of the same polarity, each surrounding a light emitting active region, are stacked and the current passes through each of them in series. Since light is emitted from both junctions the same light output can be obtained with reduced current density and higher efficiency.

The drawback of the cascade LED, however, is its high operating voltage (unavoidable for multiple junctions connected in series). Even with the efficiency gains by reducing current density, a cascade LED stills need to be operated above 10 A/cm² to match the flux of a conventional LED at 40 A/cm². The cascade LED forward voltage will exceed 6V, and such a high voltage limits the range of possible applications. For example, a 6V cascade LED could not be used to upgrade existing illumination systems designed with 3.5V drivers.

Accordingly, there is a need for improved LED devices.

### SUMMARY

Embodiments of the disclosure are directed to LED devices and methods for manufacturing LED devices. In one or more embodiments, a light emitting diode (LED) device comprises: a first light emitting stack on a second light emitting stack, wherein the first light emitting stack comprises a first n-type layer on a first tunnel junction, the first tunnel junction on a first p-type layer, and the first p-type layer on a first light-emitting active region, the second light emitting stack comprises a second n-type layer in contact with the first light-emitting active region and on a second light-emitting active region, the second light-emitting active region on a second p-type layer; and a metal contact on the second light emitting stack and extending to the first light emitting stack.

Additional embodiment of the disclosure is directed to methods of manufacturing LED devices. In one or more embodiments, a method of manufacturing a light-emitting diode (LED) die comprises: epitaxially growing a first light emitting stack and a second light emitting stack on an epitaxial wafer, the first light emitting stack comprising a first n-type layer on a first tunnel junction, the first tunnel junction on a first p-type layer, and the first p-type layer on a first light-emitting active region, the second light emitting stack comprising a second n-type layer in contact with the first light-emitting active region and on a second light-emitting active region, the second light-emitting active region on a second p-type layer; and forming at least one metal contact on the second p-n junction.

A further embodiment of the disclosure is directed to a method of manufacturing thin film flip chip (TFFC) die. In one or more embodiments, a method of manufacturing thin film flip chip (TFFC) die comprises: sequentially forming two p-n junctions on an epitaxial wafer to form an epitaxial stack, the epitaxial stack comprising at least one n-type layer and at least one p-type layer and having a light-emitting active region embedded between the at least one n-type layer and at least one p-type layer; dry etching the epitaxial stack to form two vias of different depths; conformally depositing a dielectric layer in the two vias; removing a portion of the dielectric layer to form contact openings; depositing one or more of an anode layer and a cathode layer in the contact openings; depositing a bonding metal layer on one or more of the anode layer or the cathode layer; singulating the thin film flip chip (TFFC) die; and bonding the thin film flip chip (TFFC) die to a sub-mount.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a cross-section schematic of an epitaxy configuration according to one or more embodiments;

FIG. 2 illustrates a cross-section schematic of an alternative epitaxy configuration according to one or more embodiments;

FIG. 3 illustrates a cross-section schematic of the epitaxy configuration of FIG. 1 after processing into a thin film flip chip (TFFC) device according to one or more embodiments;

FIG. 4 illustrates a cross-section schematic of the alternative epitaxy configuration of FIG. 2 after processing into a thin film flip chip (TFFC) device according to one or more embodiments;

FIG. 5 illustrates a cross-section schematic of the epitaxy configuration of FIG. 2 after processing into a lateral die according to one or more embodiments;

FIG. 6 illustrates a process flow diagram for a method of forming a LED die according to one or more embodiments;

FIG. 7 illustrates a process flow diagram for a method of forming a thin film flip chip (TFFC) device according to one or more embodiments;

FIG. 8 illustrates an example of a general device in accordance with some embodiments;

FIG. 9 illustrates an example lighting system, according to some embodiments;

FIG. 10 illustrates an example hardware arrangement for implementing the above disclosed subject matter, according to some embodiments;

FIG. 11 shows a block diagram of an example of a system, according to some embodiments; and

FIG. 12 illustrates an example method of fabricating an illumination device, according to some embodiments.

To facilitate understanding, identical reference numerals have been used, where possible, to designate identical elements that are common to the figures. The figures are not drawn to scale. For example, the heights and widths of the mesas are not drawn to scale.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate or on a substrate with one or more layers, films, features, or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN, and other alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed is also performed on an underlayer formed on the substrate, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Examples of different light illumination systems and/or light emitting diode (LED) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

Semiconductor light emitting devices or optical power emitting devices, such as devices that emit ultraviolet (UV) or infrared (IR) optical power, are among the most efficient light sources currently available. These devices may include light emitting diodes, resonant cavity light emitting diodes, vertical cavity laser diodes, edge emitting lasers, or the like (hereinafter referred to as “LEDs”). Due to their compact size and lower power requirements, for example, LEDs may be attractive candidates for many different applications. For example, they may be used as light sources (e.g., flashlights and camera flashes) for hand-held battery-powered devices, such as cameras and cell phones. They may also be used, for example, for automotive lighting, heads up display (HUD) lighting, horticultural lighting, street lighting, torch for video, general illumination (e.g., home, shop, office and studio lighting, theater/stage lighting and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro-LED arrays, etc.) may be used for applications where more brightness is desired or required.

The present disclosure generally relates to the manufacture of green light sources for applications in high power general illumination systems.

Embodiments described herein describe LED devices and methods for forming LED devices. In particular, the present disclosure describes LED devices and methods to produce LED devices which are comprised of a first and a second p-n junction deposited sequentially on the same wafer, the first and second junctions having opposite orders of deposition of the n- and p-layers. One light-emitting active region is embedded between the n- and p-layers of the first junction, and another light-emitting active region is embedded between the n- and p-layers of the second junction. In one or more embodiments, both active regions emit the same color, and efficiency benefits are expected mainly for cyan or longer wavelength light. Contacts are processed such that forward current can be passed in parallel through both of the junctions using a single voltage source. For a given forward current, the disclosed LED operates at lower voltage with higher optical flux and efficiency than a standard LED with a similar light-emitting active region.

As used herein, the term “p-n junction” refers to a boundary between two semiconductor layers of opposite conductivity types p-type and n-type. The “p” side contains an excess of holes, while the “n” side contains an excess of electrons. The excesses of holes and electrons may be obtained by intentional doping with acceptor or donor impurities, respectively, and/or may result from the presence of native crystal defects. Said boundary is not necessarily abrupt, planar, or smooth. Said boundary may include of gradients in impurity concentration and/or layers of intrinsic (neutral) conductivity type between the p-type and n-type layers. Said boundary may feature protrusions of p-type semiconductor into the n-type semiconductor, or vice-versa.

One or more embodiments requires nitride epitaxy with a p-type layer grown before the quantum wells (p-side down), which is opposite the usual case with the n-type layer grown before the quantum wells. There has been a widely held perception that high-efficiency p-side down LEDs are infeasible due to unintentional acceptor dopant incorporation in the quantum wells. In one or more embodiments, however, an unintentional acceptor dopant incorporation in the quantum wells is advantageously mitigated using special growth conditions to produce a high-efficiency p-side down LED. For current densities relevant to illumination, the deficit in EQE between p-side down and conventional LEDs is at present not large and can be further reduced.

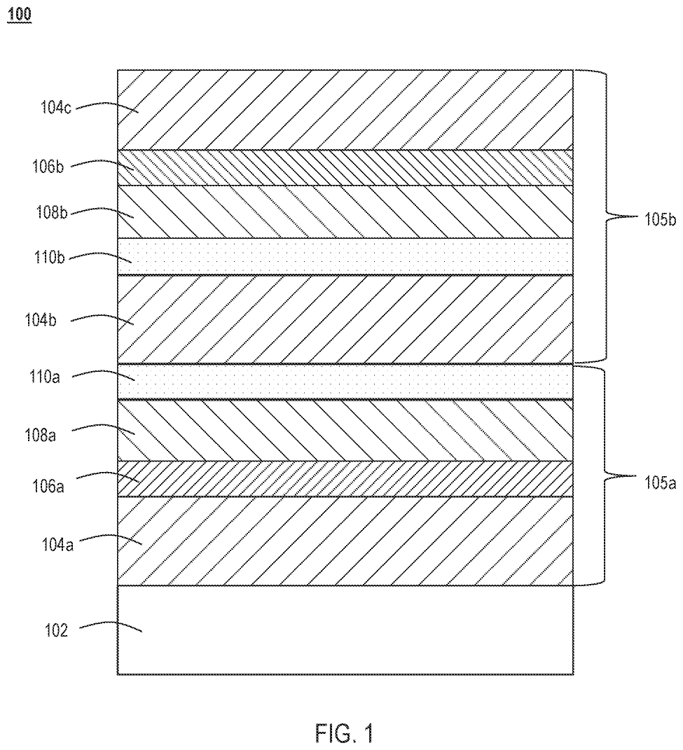

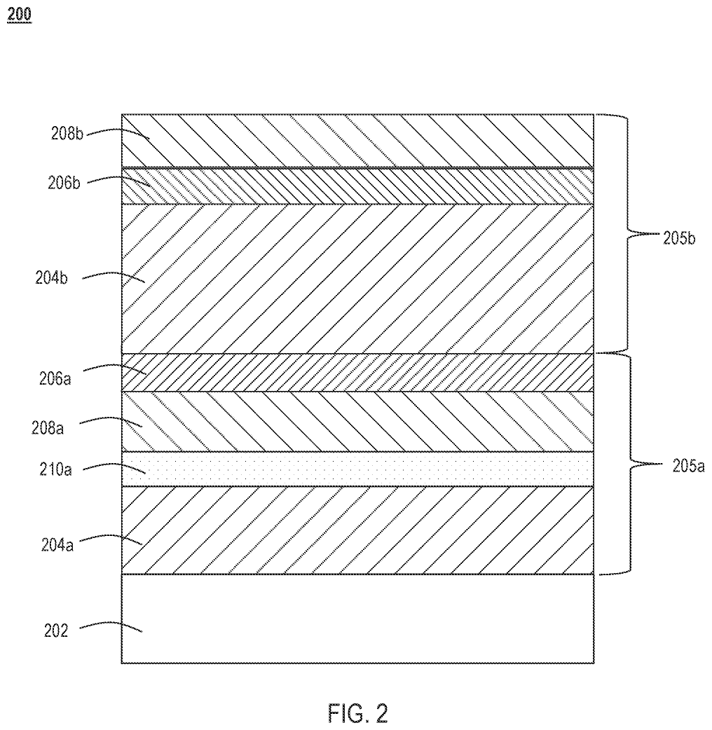

In one or more embodiments, there are two general configurations of epitaxy that are used to produce the desired dual-active region LEDs. Although the examples discussed herein are for the thin film flip chip (TFFC) die architecture, the same epitaxy designs could be processed into other die architectures using similar fabrication methods. Chip-scale package, vertical thin-film, and lateral die are other possible architectures. In the first epitaxy configuration, which is depicted in FIG. 1, all metal contacts can be made to n-type layers, and the polarity of the contacts is the same as in a traditional device. In the second or alternative epitaxy configuration, which is depicted in FIG. 2, only one tunnel junction needs to be grown, making the epitaxy easier to grow.

The embodiments of the disclosure are described by way of the Figures, which illustrate devices and processes for forming devices in accordance with one or more embodiments of the disclosure. The processes shown are merely illustrative possible uses for the disclosed processes, and the skilled artisan will recognize that the disclosed processes are not limited to the illustrated applications.

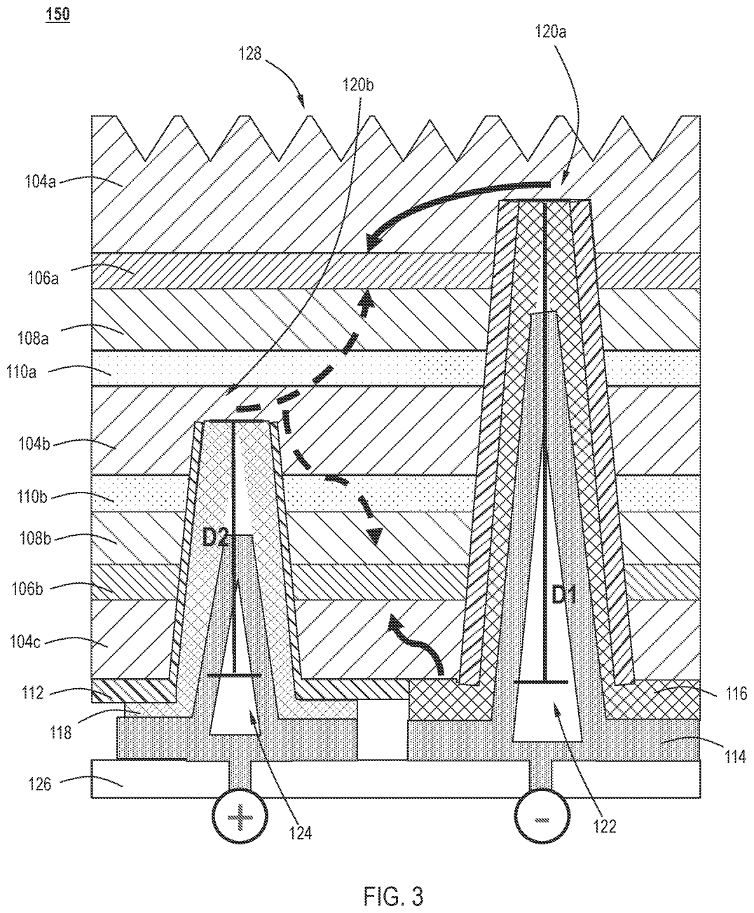

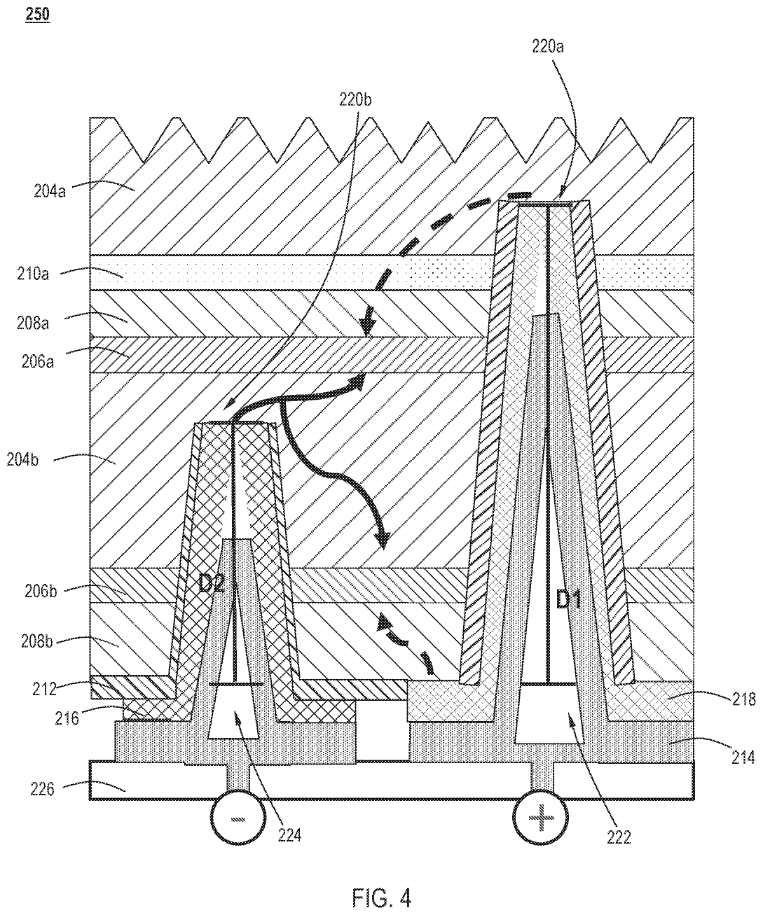

One or more embodiments of the disclosure are described with reference to the Figures. FIG. 1 illustrates a cross-sectional schematic of an epitaxy configuration 100, “configuration A”, according to one or more embodiments. FIG. 2 illustrates a cross-sectional schematic of an alternative epitaxy configuration 200, “configuration B”, according to one or more alternative embodiments. An additional aspect of the disclosure pertains to a method of manufacturing a thin film flip chip (TFFC) device from the epitaxy configurations, as illustrated in FIGS. 3 and 4.

Referring to FIG. 1, a dual-active region LED wafer 100 is manufactured by forming a plurality of III-nitride layers on a substrate 102 to form two p-n junction LEDs on the substrate including light-emitting active regions. The two p-n junctions are connected in parallel. The light-emitting active regions include a first light-emitting active region 106a and a second light-emitting active region 106b. Any order of stacking the different active regions is within the scope of the disclosure.

According to certain specific embodiments, the dual-active region LED wafer 100 comprises a first light emitting stack 105a having a first n-type layer 104a formed on the substrate 102, a first light-emitting active region 106a grown on the first n-type layer 104a, a first p-type layer 108a formed on the first light-emitting active region 106a, and a first tunnel junction 110a formed on the first p-type layer 108a.

In one or more embodiments, the first light-emitting active region 106a is a green light emitting active region. In the embodiment shown, there is a first tunnel junction 110a on the first junction, in particular on the first p-type layer 108a. A tunnel junction is a structure that allows electrons to tunnel from the valence band of a p-type layer to the conduction band of an n-type layer in reverse bias. When an electron tunnels, a hole is left behind in the p-type layer, such that carriers are generated in both regions. Accordingly, in an electronic device like a diode, where only a small leakage current flows in reverse bias, a large current can be carried in reverse bias across a tunnel junction. A tunnel junction comprises a particular alignment of the conduction and valence bands at the p/n tunnel junction. This can be achieved by using very high doping (e.g., in the p++/n++ junction). In addition, III-nitride materials have an inherent polarization that creates an electric field at heterointerfaces between different alloy compositions. In some circumstances, this polarization field can also be utilized to achieve band alignment for tunneling.

Still referring to FIG. 1, the dual-active region LED wafer 100 further comprises a second light emitting stack 105b on the first light emitting stack 105a. The second light emitting stack 105b includes a second n-type layer 104b on the first tunnel junction 110a, a second tunnel junction 110b on the second n-type layer 104b, a second light-emitting active region 106b grown on a second p-type layer 108b, and a third n-type layer 104c on the second light-emitting active region 106b. In one or more embodiments, the second light-emitting active region 106b is also a green light emitting active region. In the embodiment shown, there is a second tunnel junction 110b on the second light emitting stack 105a, in particular on the second n-type layer 104b.

In one or more embodiments, a nucleation layer (not illustrated) and dislocation density control layers (not illustrated) are grown on a suitable substrate 102, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, first n-type layer 104a is grown on the substrate 102, the nucleation layer, and/or the dislocation density control layers. In one or more embodiments, a first n-type layer 104a is formed on the substrate 102. The substrate 102 may be any substrate known to one of skill in the art which is configured for use in the formation of LED devices. In one or more embodiments, the substrate 102 comprises one or more of sapphire, silicon carbide, silicon (Si), quartz, magnesium oxide (MgO), zinc oxide (ZnO), spinel, and the like. In one or more embodiments, the substrate 102 is a transparent substrate. In specific embodiments, the substrate 102 comprises sapphire. In one or more embodiments, the substrate 102 is not patterned prior to formation of the LEDs. Thus, in some embodiments, the substrate is 102 not patterned and can be considered to be flat or substantially flat. In other embodiments, the substrate 102 is a patterned substrate.

In one or more embodiments, the first n-type layer 104a, the second n-type layer 104b, and the third n-type layer 104c may comprise any Group III-V semiconductors, including binary, ternary, and quaternary alloys of gallium (Ga), aluminum (Al), indium (In), and nitrogen (N), also referred to as III-nitride materials. Thus, in some embodiments, the first n-type layer 104a, the second n-type layer 104b, and the third n-type layer 104c independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In a specific embodiment, the first n-type layer 104a, the second n-type layer 104b, and the third n-type layer 104c comprise gallium nitride (GaN). In one or more embodiments, the first n-type layer 104a, the second n-type layer 104b, and the third n-type layer 104c are independently doped with n-type dopants, such as silicon (Si) or germanium (Ge). In one or more embodiments, the dopant concentration is in a range of from 1 e17 to 2e19 cm³. In one or more embodiments, the first n-type layer 104a may have a thickness in the range of from 1 μm to 3 μm to ensure a wide process margin for a subsequent etching step used to contact this layer.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g., a III-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition” refers to a process in which films of materials are deposited from the vapor phase by decomposition of chemicals on a substrate surface. In CVD, a substrate surface is exposed to precursors and/or co-reagents simultaneous or substantially simultaneously. A particular subset of CVD processes commonly used in LED manufacturing use metalorganic precursor chemical and are referred to as MOCVD or metalorganic vapor phase epitaxy (MOVPE). As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. In a PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similar to a thermal ALD process, a purge step may be conducted between the deliveries of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, μLED array 100 is manufactured by placing the substrate 102 in a metalorganic vapor-phase epitaxy (MOVPE) reactor so that the μLED array layers are grown epitaxially.

In one or more embodiments, after the growth of the first n-type layer 104a, a first light-emitting active region 106a is grown. The first light-emitting active region 106a consists of multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for green LEDs ranges from 4 to 12, the typical barrier thickness ranges from 5 nm to 25 nm, the well thickness ranges from 1 nm to 5 nm, and the well indium concentration ranges from 15% indium to 25% indium. In some embodiments, the active region may be doped with Si or Ge, while in other embodiments, the active region is undoped. After the first light-emitting active region 106a is grown, a first p-type layer 108a is grown on the first light-emitting active region.

In one or more embodiments, the first p-type layer 108a and the second p-type layer 108b may independently comprise any Group III-V semiconductors, including binary, ternary, and quaternary alloys of gallium (Ga), aluminum (Al), indium (In), and nitrogen (N), also referred to as III-nitride materials. Thus, in some embodiments, the first p-type layer 108a and the second p-type layer 108b independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In one or more embodiments, magnesium (Mg) is the acceptor dopant for the first p-type layer 108a. A first tunnel junction 110a is then grown, comprised of heavily doped p-GaN and n-GaN layers with doping concentrations in the range 10¹⁹-10²¹ cm⁻³ and layer thickness typically less than 50 nm. The first tunnel junction 110a may also utilize thin InGaN or graded InGaN layers disposed between highly doped GaN layers.

In some embodiments, the first p-type layer 108a and the second p-type layer 108b independently comprise a sequence of doped p-type layers. In one or more embodiments, the first p-type layer 108a and the second p-type layer 108b independently comprise a gallium nitride (GaN) layer. The first p-type layer 108a and the second p-type layer 108b may be independently doped with any suitable p-type dopant known to the skilled artisan. In one or more embodiments, the first p-type layer 108a and the second p-type layer 108b may independently be doped with magnesium (Mg). In one or more embodiments, the first p-type layer 108a and the second p-type layer 108b independently comprise a first magnesium doped p-type aluminum gallium nitride layer, a magnesium doped p-type gallium nitride layer, and a second magnesium doped p-type aluminum gallium nitride layer.

In one or more embodiments, a second n-type layer 104b is grown. To ensure an even current distribution within the device, it may be advantageous to match the sheet resistance of the first and second n-type layers 104a, 104b, however, non-matching implementations are possible with differences in spacings of first and second sets of contact vias to be discussed below. In one or more embodiments, the second n-type layer 104b has a thickness of at least 100 nm in order to be able to subsequently place an etched contact within this layer. An AlGaN layer (not illustrated) may be embedded within the second n-type layer 104b to facilitate controlled etching to a particular depth.

After the second n-type layer is grown, a second tunnel junction 110b is grown. The design of the second tunnel junction may be the same or different from the first tunnel junction 110a.

In one or more embodiments, after the second tunnel junction 110b is grown, a second p-type layer 108b is grown, followed by a second light-emitting active region 106b. The general range of parameter limits is the same for the second light-emitting active region 106b as for the first light-emitting active region 106a, however some differences in specific details may be needed to obtain similar characteristics for the first and second active regions having opposite polarities. Matching their characteristics is desirable to ensure that for given voltage the current flowing through the first and second active regions is similar.

In one or more embodiments, the epitaxy is ended with growth of a third n-type layer 104c. In the embodiments depicted in FIGS. 3 and 4, the third n-type layer 104c is not a current spreading layer and so it may be grown with lower thickness and doping than the first two n-type layers.

FIG. 3 illustrates a cross-section schematic after processing the first variation 100 of FIG. 1 into a thin film flip chip (TFFC) die design. The die is designed with electrical contacts such that the “middle” n-type layer of the structure is a common cathode (or common anode) to both of the two p-n junctions in the stack. It is a common anode for the first variation A 100 of FIG. 1 and a common cathode for the second variation B 200 of FIG. 2. Examples of a possible thin film flip chip (TFFC) die design are illustrated in FIGS. 3 and 4. In one or more embodiments, an extra set of contact vias that is not needed in a standard LED die (or cascade LED) is required, however the EQE droop and voltage advantage from sharing current through two active regions can outweigh the disadvantage of losing some active area to the extra vias.

After epitaxial growth, the wafer is processed through the fabrication steps below resulting in an LED die that appears in cross-section as shown in FIG. 3. For growth on a patterned sapphire substrate, the final step on the list may be omitted. The main difference from a standard TFFC die design and the design of one or more embodiments herein is the second set of vias needed to contact the second n-type layer 104b.

Referring to FIG. 3, two sets of vias 120a, 120b are dry etched to form the TFFC die design 150. The vias 120a, 120b have different depths, D1, D2. In one or more embodiments, D2 can range from 0.1 microns to 1.0 microns, and D1 can range from 0.4 microns to 3 microns.

In one or more embodiments, the epitaxy stack of FIG. 1 is first subjected to an acceptor activation anneal. In some embodiments, it is preferable to do the acceptor activation anneal after dry etching in order to allow for hydrogen to escape buried p-type layers through the via side walls.

In one or more embodiments, a conformal dielectric layer 112 is deposited in the vias 120a, 120b. As used herein, the term “dielectric” refers to an electrical insulator material that can be polarized by an applied electric field. In one or more embodiments, the dielectric layer includes, but is not limited to, oxides, e.g., silicon oxide (SiO₂), aluminum oxide (Al₂O₃), nitrides, e.g., silicon nitride (Si₃N₄). In one or more embodiments, the dielectric layer comprises silicon nitride (Si₃N₄), silicon oxide (SiO₂), or a multi-layer of silicon dioxide (SiO₂) and silicon nitride (Si₃N₄). In some embodiments, the dielectric layer composition is non-stoichiometric relative to the ideal molecular formula. For example, in some embodiments, the dielectric layer includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

Still referring to FIG. 3, in one or more embodiments, a portion of the dielectric layer 112 is removed with dry etching to form contact openings 122, 124. A cathode metal layer 116 is deposited in a contact opening 122 in the deeper via 120a along the sidewalls of the via 120a. The cathode metal layer 116 may comprise any suitable material known to the skilled artisan. In one or more embodiments, the cathode metal layer 116 is any high reflectivity metal that makes ohmic contact with the n-type layers. In one or more specific embodiments, the cathode metal layer 116 comprises an n-contact material selected from one or more of silver (Ag) and aluminum (Al).

In one or more embodiments, an anode metal layer 118 is deposited in a contact opening 124 in the shallower via 120b along the sidewalls of the via 120b. The anode metal layer 118 may comprise any suitable material known to the skilled artisan. In one or more embodiments, the anode metal layer 118 is any high reflectivity metal that makes ohmic contact with the n-type layers. In some embodiments, the anode metal layer 118 and the cathode metal layer 116 comprise the same material and are deposited in the same step and are patterned using a technique such as lift-off or dry etching. In one or more specific embodiments, the anode metal layer 118 comprises an n-contact material selected from one or more of silver (Ag) and aluminum (Al).

In one or more embodiments, a bonding metal layer 114 is deposited in the contact openings 122, 124. In some embodiments, the bonding metal layer 114 is a thicker metal layer of different composition than the cathode metal layer 116 and the anode metal layer 118 in order to facilitate subsequent bonding to the submount. In one or more embodiments, the metal of the bonding metal layer 114 may be comprised of any suitable material known to the skilled artisan. In one or more embodiments, the bonding metal layer 114 comprises one or more of titanium (Ti) and gold (Au).

With reference to FIG. 3, in one or more embodiments, the die is singulated. The die is then bonded to a sub-mount 126 using a technique such as gold-gold interconnect bonding. The final step is laser lift-off, followed by photoelectrochemical etching to texture the surface 128.

FIG. 2 illustrates a cross-sectional schematic of an alternative epitaxy configuration 200, “configuration B”, according to one or more alternative embodiments. An additional aspect of the disclosure pertains to a method of manufacturing a thin film flip chip (TFFC) device from the epitaxy configurations, as illustrated in FIG. 4.

Referring to FIG. 2, a dual-active region LED 200 is manufactured by forming a plurality of III-nitride layers on a substrate 202 to form two p-n junction LEDs on the substrate including light-emitting active regions. The two p-n junctions are connected in parallel. The light-emitting active regions include a first light-emitting active region 106a and a second light-emitting active region 106b. Any order of stacking the different active regions is within the scope of the disclosure.

According to certain specific embodiments, the dual-active region LED 200 comprises a first light emitting stack 205a having a first n-type layer 204a formed on the substrate 202, a first tunnel junction 210a formed on the first n-type layer 204a, a first p-type layer 208a formed on the first tunnel junction 210a, and a first light-emitting active region 206a is grown on the first p-type layer 208a.

In one or more embodiments, the first light-emitting active region 206a is a green light emitting active region. In the embodiment shown, there is a first tunnel junction 210a on the first junction, in particular on the first n-type layer 204a.

Still referring to FIG. 2, the dual-active region LED 200 further comprises a second light emitting stack 205b on the first light emitting stack 205a. The second light emitting stack 205b includes a second n-type layer 204b on the first light-emitting active region 206a, a second light-emitting active region 206b on the second n-type layer 204b, and a second p-type layer 208b on the second light-emitting active region 206b. In one or more embodiments, the second light-emitting active region 206b is also a green light emitting active region.

In one or more embodiments, a nucleation layer (not illustrated) and dislocation density control layers (not illustrated) are grown on a suitable substrate 202, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, first n-type layer 204a is grown on the substrate 202, the nucleation layer, and/or the dislocation density control layers. In one or more embodiments, a first n-type layer 204a is formed on the substrate 202. The substrate 202 may be any substrate known to one of skill in the art which is configured for use in the formation of LED devices. In one or more embodiments, the substrate 202 comprises one or more of sapphire, silicon carbide, silicon (Si), quartz, magnesium oxide (MgO), zinc oxide (ZnO), spinel, and the like. In one or more embodiments, the substrate 202 is a transparent substrate. In specific embodiments, the substrate 202 comprises sapphire. In one or more embodiments, the substrate 202 is not patterned prior to formation of the LEDs. Thus, in some embodiments, the substrate is 202 not patterned and can be considered to be flat or substantially flat. In other embodiments, the substrate 202 is a patterned substrate.

In one or more embodiments, the first n-type layer 204a and the second n-type layer 204b may comprise any Group III-V semiconductors, including binary, ternary, and quaternary alloys of gallium (Ga), aluminum (Al), indium (In), and nitrogen (N), also referred to as III-nitride materials. Thus, in some embodiments, the first n-type layer 204a and the second n-type layer 204b independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In a specific embodiment, the first n-type layer 204a and the second n-type layer 204b comprise gallium nitride (GaN). In one or more embodiments, the first n-type layer 204a and the second n-type layer 204b are independently doped with n-type dopants, such as silicon (Si) or germanium (Ge). In one or more embodiments, the dopant concentration is in a range of from 1 e17 to 2e19 cm³. In one or more embodiments, the first n-type layer 204a may have a thickness in the range of from 1 μm to 3 μm to ensure a wide process margin for a subsequent etching step used to contact this layer.

In one or more embodiments, dual-active region LED 200 is manufactured by placing the substrate 202 in a metalorganic vapor-phase epitaxy (MOVPE) reactor so that the dual-active region LED layers are grown epitaxially.

In one or more embodiments, after the growth of the first n-type layer 204a, a first tunnel junction 210a is grown, followed by growth of the first p-type layer 208a. In one or more embodiments, the first tunnel junction 110a is comprised of heavily doped p-GaN and n-GaN layers with doping concentrations in the range 10¹⁹-10²¹ cm⁻³ and layer thickness typically less than 50 nm. In one or more embodiments, the first p-type layer 208a and the second p-type layer 208b may independently comprise any Group III-V semiconductors, including binary, ternary, and quaternary alloys of gallium (Ga), aluminum (Al), indium (In), and nitrogen (N), also referred to as III-nitride materials. Thus, in some embodiments, the first p-type layer 208a and the second p-type layer 208b independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In one or more embodiments, magnesium (Mg) is the acceptor dopant for the first p-type layer 208a.

In some embodiments, the first p-type layer 208a and the second p-type layer 208b independently comprise a sequence of doped p-type layers. In one or more embodiments, the first p-type layer 208a and the second p-type layer 208b independently comprise a gallium nitride (GaN) layer. The first p-type layer 208a and the second p-type layer 208b may be independently doped with any suitable p-type dopant known to the skilled artisan. In one or more embodiments, the first p-type layer 208a and the second p-type layer 208b may independently be doped with magnesium (Mg). In one or more embodiments, the first p-type layer 208a and the second p-type layer 208b independently comprise a first magnesium doped p-type aluminum gallium nitride layer, a magnesium doped p-type gallium nitride layer, and a second magnesium doped p-type aluminum gallium nitride layer.

A first light-emitting active region 206a is then grown. The first light-emitting active region 206a consists of multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for green LEDs ranges from 4 to 12, the typical barrier thickness ranges from 5 nm to 25 nm, the well thickness ranges from 1 nm to 5 nm, and the well indium concentration ranges from 15% indium to 25% indium. In some embodiments, the active region may be doped with Si or Ge, while in other embodiments, the active region is undoped.

In one or more embodiments, a second n-type layer 204a is grown on the first light-emitting active region 206a. To ensure an even current distribution within the device, it may be advantageous to match the sheet resistance of the first and second n-type layers 204a, 204b, however, non-matching implementations are possible with differences in spacings of first and second sets of contact vias to be discussed below. In one or more embodiments, the second n-type layer 204b has a thickness of at least 100 nm in order to be able to subsequently place an etched contact within this layer. An AlGaN layer (not illustrated) may be embedded within the second n-type layer 204b to facilitate controlled etching to a particular depth.

After the second n-type layer 204b is grown, a second light-emitting active region 206b is grown, followed by growth of a second p-type layer 208b. The general range of parameter limits is the same for the second light-emitting active region 206b as for the first light-emitting active region 206a, however some differences in specific details may be needed to obtain similar characteristics for the first and second active regions having opposite polarities. It is desirable to ensure that, for given voltage, the current flowing through the first and second active regions is similar.

FIG. 4 illustrates a cross-section schematic after processing the second variation 200 of FIG. 2 into a thin film flip chip (TFFC) die design. After epitaxial growth, the wafer is processed through the fabrication steps below resulting in an LED die that appears in cross-section as shown in FIG. 4. For growth on a patterned sapphire substrate, the final step on the list may be omitted. The main difference from a standard TFFC die design and the design of one or more embodiments herein is the second set of vias needed to contact the second n-type layer 204b.

Referring to FIG. 4, two sets of vias 220a, 220b are dry etched to form the TFFC die design 250. The vias 220a, 220b have different depths, D1, D2. In one or more embodiments, D2 can range from 0.1 microns to 1.0 microns, and D1 can range from 0.4 microns to 3 microns.

In one or more embodiments, the epitaxy stack of FIG. 2 is first subjected to an acceptor activation anneal. In some embodiments, it is preferable to do the acceptor activation anneal after dry etching in order to allow for hydrogen to escape buried p-type layers through the via side walls.

In one or more embodiments, a conformal dielectric layer 212 is deposited in the vias 220a, 220b. In one or more embodiments, the dielectric layer includes, but is not limited to, oxides, e.g., silicon oxide (SiO₂), aluminum oxide (Al₂O₃), nitrides, e.g., silicon nitride (Si₃N₄). In one or more embodiments, the dielectric layer comprises silicon nitride (Si₃N₄), silicon oxide (SiO₂), or a multi-layer of silicon dioxide (SiO₂) and silicon nitride (Si₃N₄). In some embodiments, the dielectric layer composition is non-stoichiometric relative to the ideal molecular formula. For example, in some embodiments, the dielectric layer includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

Still referring to FIG. 4, in one or more embodiments, a portion of the dielectric layer 212 is removed with dry etching to form contact openings 222, 224. A cathode metal layer 216 is deposited in a contact opening 224 in the deeper via 220a along the sidewalls of the via 220a. The cathode metal layer 216 may comprise any suitable material known to the skilled artisan. In one or more embodiments, the cathode metal layer 216 is any high reflectivity metal that makes ohmic contact with the n-type layers. In one or more specific embodiments, the cathode metal layer 216 comprises an n-contact material selected from one or more of silver (Ag) and aluminum (Al).

In one or more embodiments, an anode metal layer 218 is deposited in a contact opening 222 in the shallower via 220b along the sidewalls of the via 220b. The anode metal layer 218 may comprise any suitable material known to the skilled artisan. In one or more embodiments, the anode metal layer 218 is any high reflectivity metal that makes ohmic contact with the n-type layers. In some embodiments, the anode metal layer 218 and the cathode metal layer 216 comprise the same material and are deposited in the same step and are patterned using a technique such as lift-off or dry etching. In one or more specific embodiments, the anode metal layer 218 comprises an n-contact material selected from one or more of silver (Ag) and aluminum (Al).

In one or more embodiments, a bonding metal layer 214 is deposited in the contact openings 222, 224. In some embodiments, the bonding metal layer 214 is a thicker metal layer of different composition than the cathode metal layer 216 and the anode metal layer 218 in order to facilitate subsequent bonding to the submount. In one or more embodiments, the metal of the bonding metal layer 214 may be comprised of any suitable material known to the skilled artisan. In one or more embodiments, the bonding metal layer 214 comprises one or more of titanium (Ti) and gold (Au).

With reference to FIG. 4, in one or more embodiments, the die is singulated. The die is then bonded to a sub-mount 226 using a technique such as gold-gold interconnect bonding. The final step is laser lift-off, followed by photoelectrochemical etching to texture the surface 228.

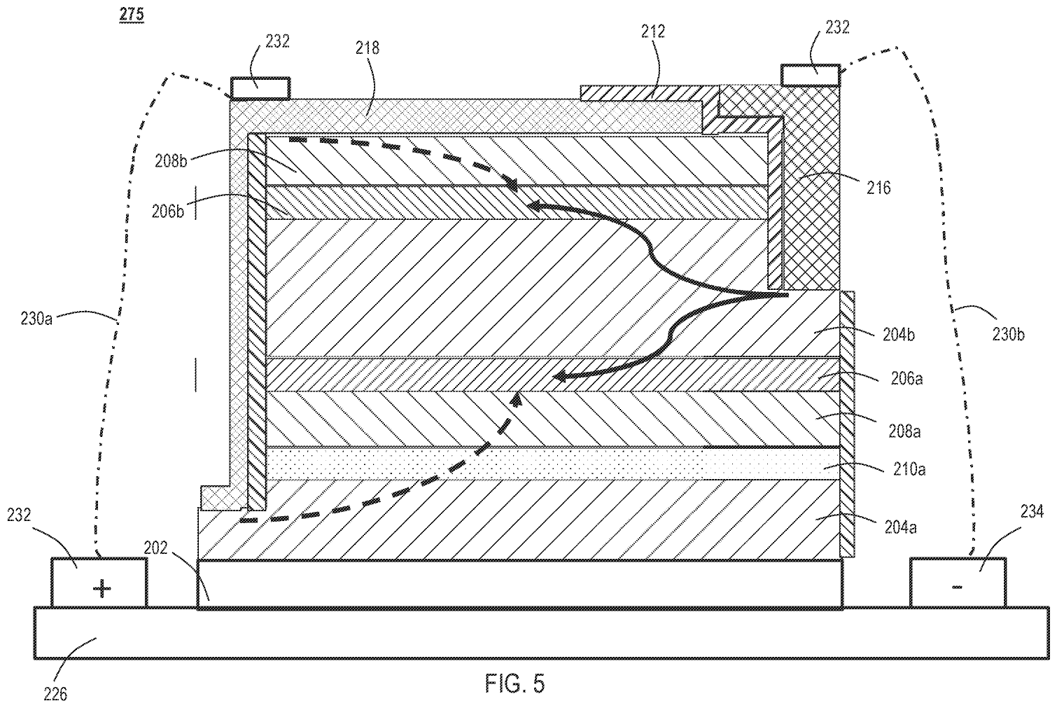

FIG. 5 illustrates a cross-section schematic of the epitaxy configuration of FIG. 2 after processing into a lateral die 275. In one or more embodiments, the lateral die 275 includes the dual-active region LED with a first light emitting stack 205a having a first n-type layer 204a formed on the substrate 202, a first tunnel junction 210a formed on the first n-type layer 204a, a first p-type layer 208a formed on the first tunnel junction 210a, and a first light-emitting active region 206a is grown on the first p-type layer 208a, and a second junction 205b on the first light emitting stack 205a. The second light emitting stack 205b includes a second n-type layer 204b on the first light-emitting active region 206a, a second light-emitting active region 206b on the second n-type layer 204b, and a second p-type layer 208b on the second light-emitting active region 206b.

In one or more embodiments, a cathode metal layer 216 extends from the second n-type layer 204b to the second p-type layer 208b. In some embodiments, cathode metal layer 216 is not in electrical contact with the second p-type layer because dielectric layer 212 is adjacent to the die and the cathode metal layer 216. In other unillustrated embodiments, the cathode metal layer 216 does not extend all the way to the top of the die. Extending the cathode metal layer 216 to the top permits additional room to include a wire bonding pad 232 keeping a narrow width of the cathode metal layer 216 on the side of the mesa of the die. The cathode metal layer 216 may comprise any suitable metal known to the skilled artisan. In one or more specific embodiments, cathode metal layer 216 comprises an n-contact material selected from one or more of silver (Ag) and aluminum (Al).

In one or more embodiments, an anode contact 218 is formed on the top surface of the second p-type layer 208b and extends to the first n-type layer 104a. The anode contact 218 can comprise any suitable material known to the skilled artisan. In one or more embodiments, the anode contact comprises transparent indium tin oxide (ITO).

In one or more embodiments, a dielectric layer 212 is formed on the die 275 to isolate the die from one or more of the anode contact 218 and the cathode metal layer 216. In one or more embodiments, the dielectric layer 212 includes, but is not limited to, oxides, e.g., silicon oxide (SiO₂), aluminum oxide (Al₂O₃), nitrides, e.g., silicon nitride (Si₃N₄). In one or more embodiments, the dielectric layer comprises silicon nitride (Si₃N₄), silicon oxide (SiO₂), or a multi-layer of silicon dioxide (SiO₂) and silicon nitride (Si₃N₄). In some embodiments, the dielectric layer 212 composition is non-stoichiometric relative to the ideal molecular formula. For example, in some embodiments, the dielectric layer includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In one or more embodiments, the lateral die 275 is mounted to a submount 226. A wire 230a may connect the positive terminal 232 of the submount 226 to the die 275. A wire 230b may connect the negative terminal 234 of the submount 226 to the die 275.

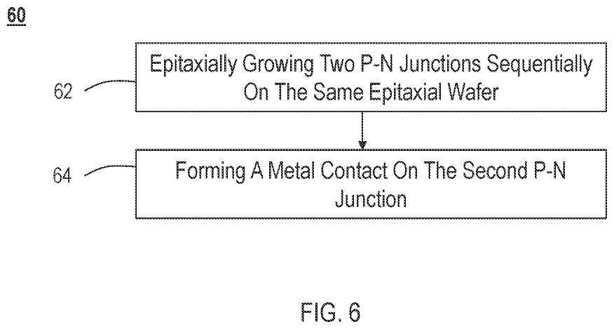

FIG. 6 illustrates a process flow diagram for a method 60 of manufacturing a dual-active region LED die according to one or more embodiments. In the method, at operation 62, two p-n junctions are epitaxially and sequentially grown on the same epitaxial wafer. At operation 64, a metal contact is formed on the second p-n junction.

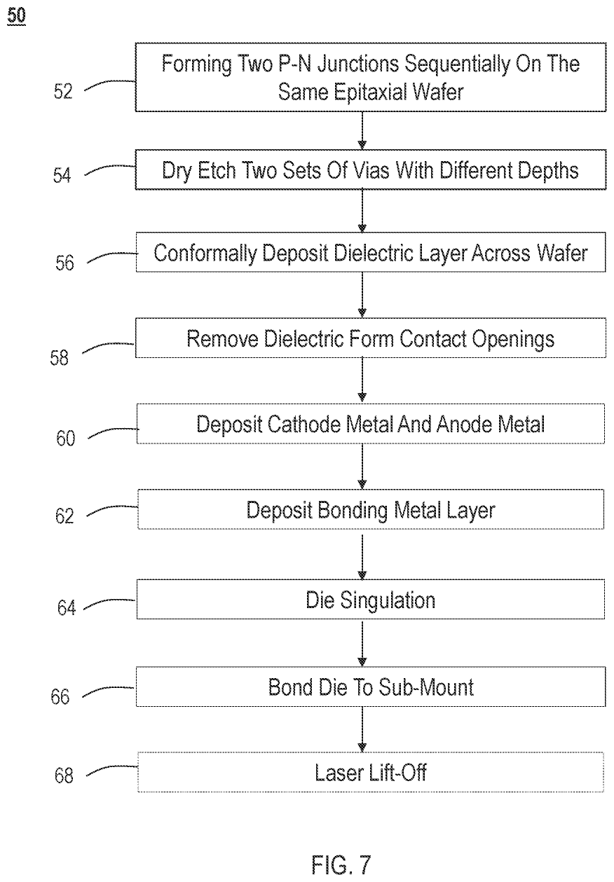

FIG. 7 illustrates a process flow diagram of a method 50 of manufacturing a thin film flip chip (TFFC) die design according to one or more embodiments of the present disclosure. With reference to FIG. 7, in one or more embodiments, the method begins at operation 52 by forming two p-n junctions sequentially on the same epitaxial wafer to form an epitaxial stack, the epitaxial stack including at least one n-type layer and at least one p-type layer and having a light-emitting active region embedded between the at least one n-type layer and at least one p-type layer. At operation 54 two sets of vias of different depths are dry etched into the epitaxial stack. At operation 56, a dielectric layer is conformally deposited in the vias. At operation 58, a portion of the dielectric layer is removed to form contact openings in the vias, the contact openings exposing the at least one n-type layer. At operation 60, a cathode metal and an anode metal are deposited in the vias on the dielectric layer. At operation 62, a bonding metal layer is deposited. At operation 64, die singulation occurs. At operation 66, the die is bonded to a sub-mount. At operation 68, laser lift-off occurs.

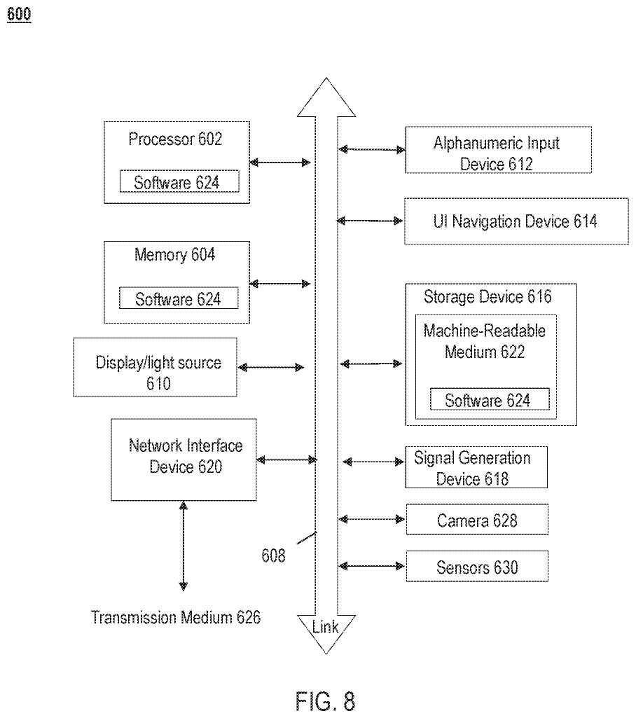

FIG. 8 illustrates an example of a general device in accordance with some embodiments. The device 600 may be a mobile device such as a laptop computer (PC), a tablet PC, a smart phone, or an augmented reality (AR)/virtual reality (VR), or an automotive device, for example. Various elements may be provided on the backplane indicated above, while other elements may be local or remote. Examples, as described herein, may include, or may operate on, logic or a number of components, modules, or mechanisms.

Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The electronic device 600 may include a hardware processor (or equivalently processing circuitry) 602 (e.g., a central processing unit (CPU), a GPU, a hardware processor core, or any combination thereof), a memory 604 (which may include main and static memory), some or all of which may communicate with each other via an interlink (e.g., bus) 608. The memory 604 may contain any or all of removable storage and non-removable storage, volatile memory or non-volatile memory. The electronic device 600 may further include a display/light source 610 such as the LEDs described above, or a video display, an alphanumeric input device 612 (e.g., a keyboard), and a user interface (UI) navigation device 614 (e.g., a mouse). In an example, the display/light source 610, input device 612 and UI navigation device 614 may be a touch screen display. The electronic device 600 may additionally include a storage device (e.g., drive unit) 616, a signal generation device 618 (e.g., a speaker), a network interface device 620, one or more cameras 628, and one or more sensors 630, such as a global positioning system (GPS) sensor, compass, accelerometer, or other sensor such as those described herein. The electronic device 600 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 616 may include a non-transitory machine readable medium 622 (hereinafter simply referred to as machine readable medium) on which is stored one or more sets of data structures or instructions 624 (e.g., software) embodying or utilized by any one or more of the techniques or functions described herein. The instructions 624 may also reside, completely or at least partially, within the memory 604 and/or within the hardware processor 602 during execution thereof by the electronic device 600. While the machine readable medium 622 is illustrated as a single medium, the term “machine readable medium” may include a single medium or multiple media (e.g., a centralized or distributed database, and/or associated caches and servers) configured to store the one or more instructions 624.

The term “machine readable medium” may include any medium that is capable of storing, encoding, or carrying instructions for execution by the electronic device 600 and that cause the electronic device 600 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 624 may further be transmitted or received over a communications network using a transmission medium 626 via the network interface device 620 utilizing any one of a number of wireless local area network (WLAN) transfer protocols or a SPI or CAN bus. Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 802.11 family of standards known as Wi-Fi, IEEE 802.16 family of standards known as WiMax, IEEE 802.16.4 family of standards, a Long Term Evolution (LTE) family of standards, a Universal Mobile Telecommunications System (UMTS) family of standards, peer-to-peer (P2P) networks, a next generation (NG)/6^{th} generation (6G) standards among others. In an example, the network interface device 620 may include one or more physical jacks (e.g., Ethernet, coaxial, or phone jacks) or one or more antennas to connect to the transmission medium 626.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single- or multi-core processor, and/or any other device capable of executing or otherwise operating computer-executable instructions, such as program code, software modules, and/or functional processes.

The camera 628 may sense light at least the wavelength or wavelengths emitted by the LEDs. The camera 628 may include optics (e.g., at least one camera lens) that are able to collect reflected light of illumination that is reflected from and/or emitted by an illuminated region. The camera lens may direct the reflected light onto a multi-pixel sensor (also referred to as a light sensor) to form an image of on the multi-pixel sensor.

The processor 602 may control and drive the LEDs via one or more drivers. For example, the processor 602 may optionally control one or more LEDs in LED arrays independent of another one or more LEDs in the LED arrays, so as to illuminate an area in a specified manner.

In addition, the sensors 630 may be incorporated in the camera 628 and/or the light source 610. The sensors 630 may sense visible and/or infrared light, and may further sense the ambient light and/or variations/flicker in the ambient light in addition to reception of the reflected light from the LEDs. The sensors may have one or more segments (that are able to sense the same wavelength/range of wavelengths or different wavelength/range of wavelengths), similar to the LED arrays.

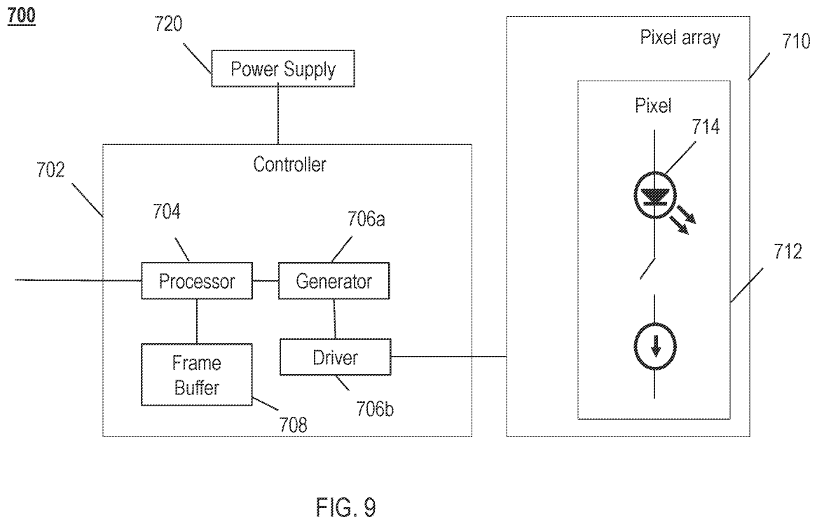

FIG. 9 illustrates an example lighting system, according to some embodiments. As above, some of the elements shown in the lighting system 700 may not be present, while other additional elements may be disposed in the lighting system 700. The lighting system 700 may include a controller 702 that controls illumination using a pixel array 710 that contains multiple individual pixels 712.

In some embodiments, some or all of the components described as the controller 702 may be disposed on a backplane such as, for example, a complementary metal oxide semiconductor (CMOS) backplane. The controller 702 may be coupled to or include one or more processors 704. The processor 704 may receive image data (in frames) via an interface and may process the image data to control a generator 706a, for example, controlling analog signals or PWM duty cycles and/or turn-on times for causing the lighting system 700 to produce the images indicated by the image data.

The controller 702 may further include a frame buffer 708. The frame buffer 708 may store one or more images prior the one or more processors 704 and store the indications for implementation by the one or more processors 704.

The generator 706a may be controlled by the processor 704 and may produce driving signals in accordance with the indications. The generator 706a may be connected to a driver 706b to drive the pixel array 710 so that the pixels 712 provide desired intensities of light.

Each pixel 712 may include one or more LEDs 714. The LEDs 714 may be different colors and may be controlled individually or in groups. As shown, the pixel 712 may include, for each pixel 712 or LED 714, a PWM switch, and a current source. The pixel 712 may be driven by the driver 706b. The signal from the generator 706a may cause the switch to open and close in accordance with the value of the signal. The signal corresponding to the intensities of light may cause the current source to produce a current flow to cause the pixels 712 to produce the corresponding intensities of light.

The lighting system 700 may further include a power supply 720. In some embodiments, the power supply 720 may be a battery that produces power for the controller 702.

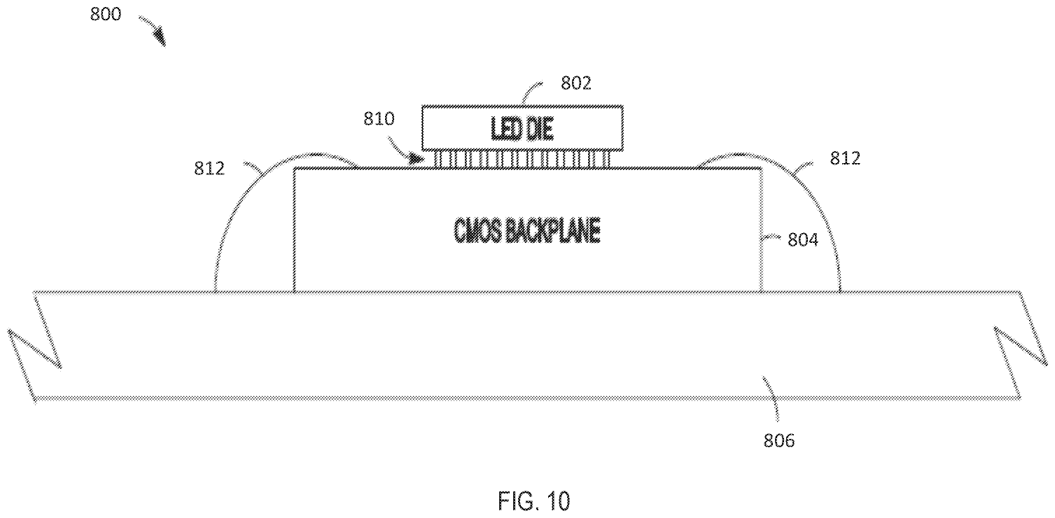

FIG. 10 illustrates an example hardware arrangement for implementing the above disclosed subject matter, according to some embodiments. In particular, the hardware arrangement 800 may include an LED die 802 that contains the LED array(s) and a backplane, such as a CMOS backplane 804. The LED die 802 may be coupled to the CMOS backplane 804 by one or more interconnects 810, where the interconnects 810 may provide for transmission of signals between the LED die 802 and the CMOS backplane 804. The interconnects 810 may comprise one or more solder bump joints, one or more copper pillar bump joints, other types of interconnects known in the art, or some combination thereof.

The LED die 802 may include circuitry to implement the LED array described above. In particular, the LED die 802 may include a plurality of LEDs. The LED die 802 may include a shared active layer and a shared substrate for the LED array, and thereby the LED array may be a monolithic LED array. Each LED of the LED array may include an individual segmented active layer and/or substrate. In some embodiments, the LED die 802 may further include switches and current sources to drive the LED array as described above. In other embodiments, the switches and the current sources may be included in the CMOS backplane 804. The LEDs may be micro-LEDs or LEDs larger than micro-LEDs.

The CMOS backplane 804 may include circuitry to implement the control module. The CMOS backplane 804 may utilize the interconnects 810 to provide the LED array with the driving signals and the signals for the intensity for causing the LED array to produce light in accordance with the signals and the intensity.

The hardware arrangement 800 may further include a PCB 806. The PCB 806 may include circuitry to implement various functionality described herein. The PCB 806 may be coupled to the CMOS backplane 804. For example, the PCB 806 may be coupled to the CMOS backplane 804 via one or more wire bonds 812. The PCB 806 and the CMOS backplane 804 may exchange image data, power, and/or feedback via the coupling, among other signals.

As shown, the LEDs and circuitry supporting the LED array can be packaged and include a submount or printed circuit board for powering and controlling light production by the LEDs. The PCB supporting the LED array may include electrical vias, heat sinks, ground planes, electrical traces, and flip chip or other mounting systems. The submount or PCB may be formed of any suitable material, such as ceramic, silicon, aluminum, etc. If the submount material is conductive, an insulating layer may be formed over the substrate material, and a metal electrode pattern formed over the insulating layer for contact with the micro-LED array. The submount can act as a mechanical support, providing an electrical interface between electrodes on the LED array and a power supply, and also provide heat sink functionality.

In general, a variety of applications may be supported by LED arrays. Such applications may include stand-alone applications to provide general illumination (e.g., within or external to a room or vehicle) or to provide specific images. In addition to devices such as a luminaire, projector, mobile device, the system may be used to provide AR and VR-based applications. Visualization systems, such as VR and AR systems, are becoming increasingly more common across numerous fields such as entertainment, education, medicine, and business. Various types of devices may be used to provide AR/VR to users, including headsets, glasses, and projectors. Such an AR/VR system may include components similar to those described above: the micro-LED array, a display or screen (which may include touchscreen elements), a micro-LED array controller, sensors, and a controller, among others. The AR/VR components can be disposed in a single structure, or one or more of the components shown can be mounted separately and connected via wired or wireless communication. Power and user data may be provided to the controller. The user data input can include information provided by audio instructions, haptic feedback, eye or pupil positioning, or connected keyboard, mouse, or game controller. The sensors may include cameras, depth sensors, audio sensors, accelerometers, two or three axis gyroscopes and other types of motion and/or environmental/wearer sensors that provide the user input data. Other sensors can include but are not limited to air pressure, stress sensors, temperature sensors, or any other suitable sensors for local or remote environmental monitoring. In some embodiments, the control input can include detected touch or taps, gestural input, or control based on headset or display position. As another example, based on the one or more measurement signals from one or more gyroscope or position sensors that measure translation or rotational movement, an estimated position of the AR/VR system relative to an initial position can be determined.

In some embodiments, the controller may control individual micro-LEDs or one or more groups of LEDs to display content (AR/VR and/or non-AR/VR) to the user while controlling other LEDs and sensors used in eye tracking to adjust the content displayed. Content display LEDs may be designed to emit light within the visible band (approximately 400 nm to 780 nm) while LEDs used for tracking may be designed to emit light in the IR band (approximately 780 nm to 2,200 nm). In some embodiments, the tracking LEDs and content LEDs may be simultaneously active. In some embodiments, the tracking LEDs may be controlled to emit tracking light during a time period that content LEDs are deactivated and are thus not displaying content to the user. The AR/VR system can incorporate optics, such as those described above, and/or an AR/VR display, for example to couple light emitted by LED array onto the AR/VR display.

In some embodiments, the AR/VR controller may use data from the sensors to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow. Based on changes in position, orientation, or movement of the AR/VR system, the system controller can send images or instructions the light emitting array controller. Changes or modification the images or instructions can also be made by user data input, or automated data input.

In general, in a VR system, a display can present to a user a view of scene, such as a three-dimensional scene. The user can move within the scene, such as by repositioning the user's head or by walking. The VR system can detect the user's movement and alter the view of the scene to account for the movement. For example, as a user rotates the user's head, the system can present views of the scene that vary in view directions to match the user's gaze. In this manner, the VR system can simulate a user's presence in the three-dimensional scene. Further, a VR system can receive tactile sensory input, such as from wearable position sensors, and can optionally provide tactile feedback to the user.

In an AR system, on the other hand, the display can incorporate elements from the user's surroundings into the view of the scene. For example, the AR system can add textual captions and/or visual elements to a view of the user's surroundings. For example, a retailer can use an AR system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the AR system can position a virtual chair in a room. The user can stand in the room on a front side of the virtual chair location to view the front side of the chair. The user can move in the room to an area behind the virtual chair location to view a back side of the chair. In this manner, the AR system can add elements to a dynamic view of the user's surroundings.

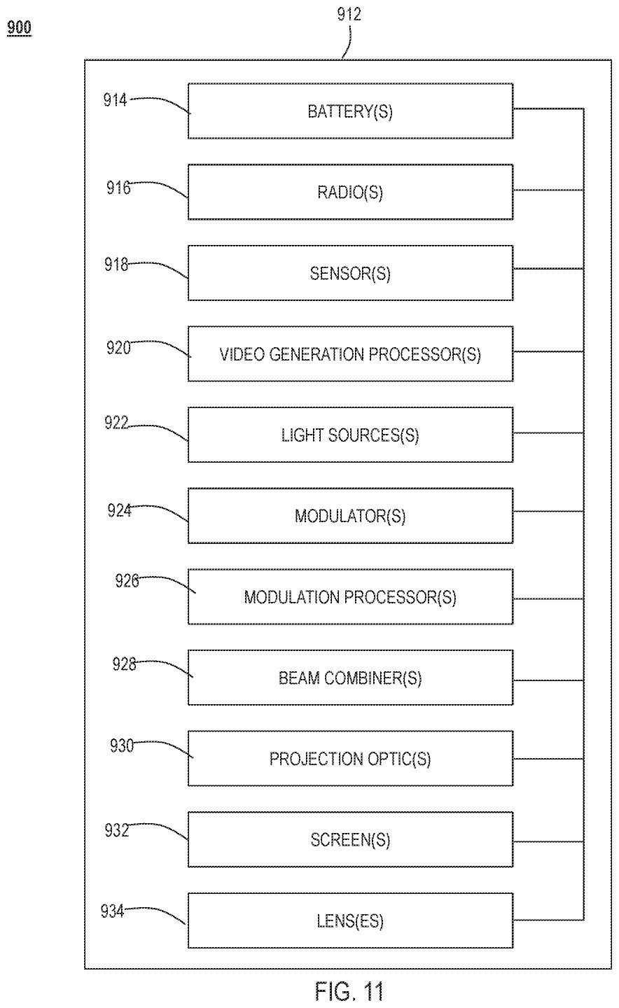

FIG. 11 shows a block diagram of an example of a system, according to some embodiments. The system 900 may provide AR/VR functionality using microLEDs. The system 900 can include a wearable housing 912, such as a headset or goggles. The housing 912 can mechanically support and house the elements detailed below. In some examples, one or more of the elements detailed below can be included in one or more additional housings that can be separate from the wearable housing 912 and couplable to the wearable housing 912 wirelessly and/or via a wired connection. For example, a separate housing can reduce the weight of wearable goggles, such as by including batteries, radios, and other elements. The housing 912 can include one or more batteries 914, which can electrically power any or all of the elements detailed below. The housing 912 can include circuitry that can electrically couple to an external power supply, such as a wall outlet, to recharge the batteries 914. The housing 912 can include one or more radios 916 to communicate wirelessly with a server or network via a suitable protocol, such as WiFi.

The system 900 can include one or more sensors 918, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 918 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an AR system, one or more of the sensors 918 can capture a real-time video image of the surroundings proximate a user.

The system 900 can include one or more video generation processors 920. The one or more video generation processors 920 can receive scene data that represents a three-dimensional scene, such as a set of position coordinates for objects in the scene or a depth map of the scene. This data may be received from a server and/or a storage medium. The one or more video generation processors 920 can receive one or more sensor signals from the one or more sensors 918. In response to the scene data, which represents the surroundings, and at least one sensor signal, which represents the location and/or orientation of the user with respect to the surroundings, the one or more video generation processors 920 can generate at least one video signal that corresponds to a view of the scene. In some examples, the one or more video generation processors 920 can generate two video signals, one for each eye of the user, that represent a view of the scene from a point of view of the left eye and the right eye of the user, respectively. In some examples, the one or more video generation processors 920 can generate more than two video signals and combine the video signals to provide one video signal for both eyes, two video signals for the two eyes, or other combinations.

The system 900 can include one or more light sources 922 that can provide light for a display of the system 900. Suitable light sources 922 can include the microLEDs above, for example. The one or more light sources 922 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The system 900 can include one or more modulators 924. The modulators 924 can be implemented in one of at least two configurations. In a first configuration, the modulators 924 can include circuitry that can modulate the light sources 922 directly. For example, the light sources 922 can include an array of light-emitting diodes, and the modulators 924 can directly modulate the electrical power, electrical voltage, and/or electrical current directed to each light-emitting diode in the array to form modulated light. The modulation can be performed in an analog manner and/or a digital manner. In some examples, the light sources 922 can include an array of red light-emitting diodes, an array of green light-emitting diodes, and an array of blue light-emitting diodes, and the modulators 924 can directly modulate the red light-emitting diodes, the green light-emitting diodes, and the blue light-emitting diodes to form the modulated light to produce a specified image.

In a second configuration, the modulators 924 can include a modulation panel, such as a liquid crystal panel. The light sources 922 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 924 can include multiple modulation panels that can modulate different colors of light. For example, the modulators 924 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 924 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The system 900 can include one or more modulation processors 926, which can receive a video signal, such as from the one or more video generation processors 920, and, in response, can produce an electrical modulation signal. For configurations in which the modulators 924 directly modulate the light sources 922, the electrical modulation signal can drive the modulators 924. For configurations in which the modulators 924 include a modulation panel, the electrical modulation signal can drive the modulation panel.

The system 900 can include one or more beam combiners 928 (also known as beam splitters), which can combine light beams of different colors to form a single multi-color beam. For configurations in which the light sources 922 can include multiple light-emitting diodes of different colors, the system 900 can include one or more wavelength-sensitive (e.g., dichroic) beam combiners 928 that can combine the light of different colors to form a single multi-color beam.

The system 900 can direct the modulated light toward the eyes of the viewer in one of at least two configurations. In a first configuration, the system 900 can function as a projector, and can include suitable projection optics 930 that can project the modulated light onto one or more screens 932. The screens 932 can be located a suitable distance from an eye of the user. The system 900 can optionally include one or more lenses 934 that can locate a virtual image of a screen 932 at a suitable distance from the eye, such as a close-focus distance, such as 500 mm, 750 mm, or another suitable distance. In some examples, the system 900 can include a single screen 932, such that the modulated light can be directed toward both eyes of the user. In some examples, the system 900 can include two screens 932, such that the modulated light from each screen 932 can be directed toward a respective eye of the user. In some examples, the system 900 can include more than two screens 932. In a second configuration, the system 900 can direct the modulated light directly into one or both eyes of a viewer. For example, the projection optics 930 can form an image on a retina of an eye of the user, or an image on each retina of the two eyes of the user.

For some configurations of AR systems, the system 900 can include at least a partially transparent display, such that a user can view the user's surroundings through the display. For such configurations, the AR system can produce modulated light that corresponds to the augmentation of the surroundings, rather than the surroundings itself. For example, in the example of a retailer showing a chair, the AR system can direct modulated light, corresponding to the chair but not the rest of the room, toward a screen or toward an eye of a user.

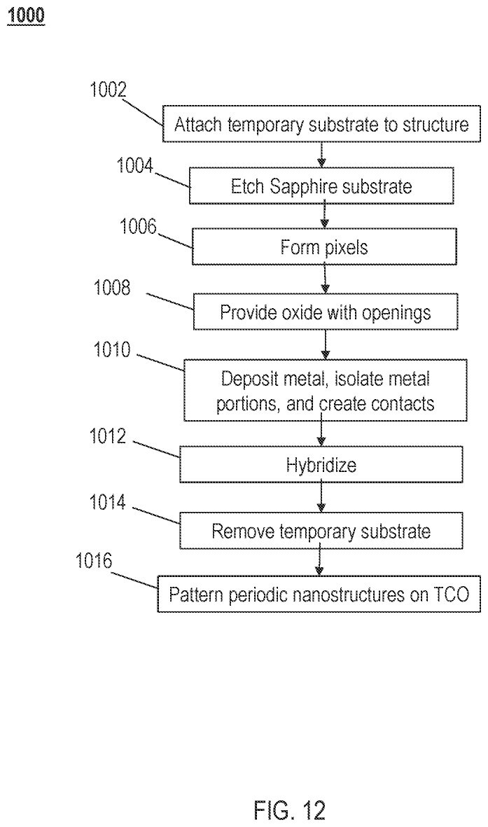

FIG. 12 illustrates an example method of fabricating an illumination device, according to some embodiments. Not all of the operations may be undertaken in the method 1000, and/or additional operations may be present. The operations may occur in a different order from that indicated in FIG. 12.

At operation 1002, a temporary substrate is attached to an initial structure that includes a Sapphire substrate and epitaxial layer (including n-type semiconductor layer, p-type semiconductor layer and active region). If a TCO layer may have been deposited on the initial structure, the temporary substrate is attached to the TCO layer.

At operation 1004, the Sapphire substrate is etched or otherwise removed and the n-type semiconductor layer is etched such that the remaining epitaxial layer has a thickness significantly less than the thickness of the initial structure.

At operation 1006, the epitaxial layer is formed into trapezoidal pixels via etching.

At operation 1008, an oxide layer is deposited on the pixels, which is then etched to expose the n-type semiconductor layer at the top of the pixel, as well as the temporary substrate or TCO layer.

At operation 1010, a metal seed layer and metal plating are deposited on the oxide layer and openings and etched to electrically isolate portions of the metal plating. Another oxide layer is deposited on the metal plating, openings are etched to expose portions of the metal plating, and a bonding layer is deposited and fabricated on the openings to provide bonding pads that contact exposed portions of the metal plating.

At operation 1012, the resulting structure is hybridized by attaching a monolithic structure to the bonding pads.

At operation 1014, the temporary substrate removed from the hybridized structure.

At operation 1016, a periodic nanostructure is patterned on the TCO layer, which may be deposited after removal of the temporary substrate if not already present.

While only certain features of the system and method have been illustrated and described herein, many modifications and changes will occur to those skilled in the art. It is, therefore, to be understood that the appended claims are intended to cover all such modifications and changes. Method operations may be performed substantially simultaneously or in a different order.

### EMBODIMENTS

Various embodiments are listed below. It will be understood that the embodiments listed below may be combined with all aspects and other embodiments in accordance with the scope of the invention.

Embodiment (a). A light-emitting diode (LED) comprising: a first light emitting stack on a second light emitting stack, wherein the first light emitting stack comprises a first n-type layer on a first tunnel junction, the first tunnel junction on a first p-type layer, and the first p-type layer on a first light-emitting active region, the second light emitting stack comprises a second n-type layer in contact with the first light-emitting active region and on a second light-emitting active region, the second light-emitting active region on a second p-type layer; and a metal contact on the second light emitting stack and extending to the first light emitting stack.

Embodiment (b). The LED die of embodiment (a), wherein the metal contact comprises one or more of a cathode layer or an anode layer.

Embodiment (c). The LED die of embodiment (a) to embodiment (b), wherein a forward current passes in parallel through the first light emitting stack and the second light emitting stack using a single voltage source.

Embodiment (d). The LED die of embodiment (a) to embodiment (c), further comprising a sub-mount.

Embodiment (e). The LED die of embodiment (a) to embodiment (d), wherein the first n-type layer, the second n-type layer, and the third n-type layer independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

Embodiment (f). The LED die of embodiment (a) to embodiment (e), wherein the first n-type layer, the second n-type layer, and the third n-type layer comprise gallium nitride (GaN).

Embodiment (g). The LED die of embodiment (a) to embodiment (f), wherein the cathode layer and the anode layer independently comprise one or more of aluminum (Al) or silver (Ag).

Embodiment (h). The LED die of embodiment (a) to embodiment (g), further comprising a dielectric layer on the LED die.

Embodiment (i). The LED die of embodiment (a) to embodiment (h), further comprising a bonding metal layer.

Embodiment (j). The LED die of embodiment (a) to embodiment (i), wherein the bonding metal layer comprises one or more of titanium (Ti) and gold (Au).

Embodiment (k). The LED die of embodiment (a) to embodiment (j), wherein one or more of the first light-emitting active region and the second light-emitting active region emits green light.

Embodiment (l). A method of manufacturing a light-emitting diode (LED) die, the method comprising: epitaxially growing a first light emitting stack and a second light emitting stack on an epitaxial wafer, the first light emitting stack comprising a first n-type layer on a first tunnel junction, the first tunnel junction on a first p-type layer, and the first p-type layer on a first light-emitting active region, the second light emitting stack comprising a second n-type layer in contact with the first light-emitting active region and on a second light-emitting active region, the second light-emitting active region on a second p-type layer; and forming at least one metal contact on the second light emitting stack.

Embodiment (m). The method of embodiment (l), wherein the metal contact comprises one or more of a cathode layer or an anode layer.

Embodiment (n). The method of embodiment (l) to embodiment (m), wherein a forward current passes in parallel through the first light emitting stack and the second light emitting stack using a single voltage source.

Embodiment (o). The method of embodiment (l) to embodiment (n), further comprising mounting the LED die to a sub-mount.

Embodiment (p). The method of embodiment (l) to embodiment (o), further comprising forming a dielectric layer on the LED die.

Embodiment (q). The method of embodiment (l) to embodiment (p), further comprising forming a bonding metal layer.

Embodiment (r). The method of embodiment (l) to embodiment (q), wherein one or more of the first light-emitting active region and the second light-emitting active region emits green light.

Embodiment (s). A method of manufacturing thin film flip chip (TFFC) die, the method comprising: sequentially forming two p-n junctions on an epitaxial wafer to form an epitaxial stack, the epitaxial stack comprising at least one n-type layer and at least one p-type layer and having a light-emitting active region embedded between the at least one n-type layer and at least one p-type layer; dry etching the epitaxial stack to form two vias of different depths; conformally depositing a dielectric layer in the two vias; removing a portion of the dielectric layer to form contact openings; depositing one or more of an anode layer and a cathode layer in the contact openings; depositing a bonding metal layer on one or more of the anode layer or the cathode layer; singulating the thin film flip chip (TFFC) die; and bonding the thin film flip chip (TFFC) die to a sub-mount.

Embodiment (t). The method of embodiment (s), wherein the epitaxial stack comprises a first light emitting stack and a second light emitting stack, the first light emitting stack comprising a first n-type layer on a first tunnel junction, the first tunnel junction on a first p-type layer, and the first p-type layer on a first light-emitting active region, and the second light emitting stack comprising a second n-type layer in contact with the first light-emitting active region and on a second light-emitting active region, the second light-emitting active region on a second p-type layer.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A light-emitting diode (LED) die comprising:
a first light emitting stack on a second light emitting stack, wherein
the first light emitting stack comprises a first n-type layer on a first tunnel junction, the first tunnel junction on a first p-type layer, and the first p-type layer on a first light-emitting active region,
the second light emitting stack comprises a second n-type layer in contact with the first light-emitting active region and on a second light-emitting active region, the second light-emitting active region on a second p-type layer; and
a metal contact on the second light emitting stack and extending to the first light emitting stack.

2. The LED die of claim 1, wherein the metal contact comprises one or more of a cathode layer or an anode layer.

3. The LED die of claim 1, wherein a forward current passes in parallel through the first light emitting stack and the second light emitting stack using a single voltage source.

4. The LED die of claim 1, further comprising a sub-mount.

5. The LED die of claim 1, wherein the first n-type layer, the second n-type layer, and the third n-type layer independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

6. The LED die of claim 5, wherein the first n-type layer, the second n-type layer, and the third n-type layer comprise gallium nitride (GaN).

7. The LED die of claim 1, wherein the cathode layer and the anode layer independently comprise one or more of aluminum (Al) or silver (Ag).

8. The LED die of claim 2, further comprising a dielectric layer on the LED die.

9. The LED die of claim 2, further comprising a bonding metal layer.

10. The LED die of claim 9, wherein the bonding metal layer comprises one or more of titanium (Ti) and gold (Au).

11. The LED die of claim 1, wherein one or more of the first light-emitting active region and the second light-emitting active region emits green light.

12. A method of manufacturing a light-emitting diode (LED) die, the method comprising:
epitaxially growing a first light emitting stack and a second light emitting stack on an epitaxial wafer, the first light emitting stack comprising a first n-type layer on a first tunnel junction, the first tunnel junction on a first p-type layer, and the first p-type layer on a first light-emitting active region, the second light emitting stack comprising a second n-type layer in contact with the first light-emitting active region and on a second light-emitting active region, the second light-emitting active region on a second p-type layer; and
forming at least one metal contact on the second light emitting stack.

13. The method of claim 12, wherein the metal contact comprises one or more of a cathode layer or an anode layer.

14. The method of claim 12, wherein a forward current passes in parallel through the first light emitting stack and the second light emitting stack using a single voltage source.

15. The method of claim 12, further comprising mounting the LED die to a sub-mount.

16. The method of claim 13, further comprising forming a dielectric layer on the LED die.

17. The method of claim 13, further comprising forming a bonding metal layer.

18. The method of claim 12, wherein one or more of the first light-emitting active region and the second light-emitting active region emits green light.

19. A method of manufacturing thin film flip chip (TFFC) die, the method comprising:
sequentially forming two p-n junctions on an epitaxial wafer to form an epitaxial stack, the epitaxial stack comprising at least one n-type layer and at least one p-type layer and having a light-emitting active region embedded between the at least one n-type layer and at least one p-type layer;
dry etching the epitaxial stack to form two vias of different depths;
conformally depositing a dielectric layer in the two vias;
removing a portion of the dielectric layer to form contact openings;
depositing one or more of an anode layer and a cathode layer in the contact openings;
depositing a bonding metal layer on one or more of the anode layer or the cathode layer;
singulating the thin film flip chip (TFFC) die; and
bonding the thin film flip chip (TFFC) die to a sub-mount.

20. The method of claim 19, wherein the epitaxial stack comprises a first light emitting stack and a second light emitting stack, the first light emitting stack comprising a first n-type layer on a first tunnel junction, the first tunnel junction on a first p-type layer, and the first p-type layer on a first light-emitting active region, and the second light emitting stack comprising a second n-type layer in contact with the first light-emitting active region and on a second light-emitting active region, the second light-emitting active region on a second p-type layer.
